(19) United States
(12) Patent Application Publication
(10) Pub. No.: US 2026/0335924 A1
(43) Pub. Date: Oct. 29, 2026

(54) SYSTEMS AND METHODS FOR AN AUTONOMOUS SPIN-COATING MICRO-LAB FOR AI-OPTIMIZED THIN-FILM PROCESSES

(71) Applicant: Arizona Board of Regents on Behalf of the University of Arizona, Tucson, AZ (US)

(72) Inventor: Majid Beidaghi, Tucson, AZ (US)

(21) Appl. No.: 19/660,042

(22) Filed: Apr. 27, 2026

Related U.S. Application Data
(60) Provisional application No. 63/794,881, filed on Apr. 25, 2025.

(51) Int. Cl. B05C 11/08; B05C 13/02; H10P 74/20

(52) U.S. Cl. CPC B05C 11/08; B05C 13/02; H10P 74/203

(57) ABSTRACT

Systems and methods for autonomous thin-film processing are disclosed. In some embodiments, a self-driving laboratory platform includes a robotic manipulator configured to transport substrates among a dispensing and spin coating station, a thermal processing station, and one or more characterization stations. The robotic manipulator can operate with interchangeable end-effectors including a substrate-handling end-effector and a liquid-dispensing end-effector. A coating solution can be dispensed onto a substrate while the substrate is supported on a spin coater chuck, and the substrate can thereafter be thermally processed and characterized using one or more electrical, optical, and imaging measurements. A controller and orchestration platform can coordinate operation of the stations, evaluate measurement data relative to a predefined target or process objective, and select parameters for a subsequent experiment in a high-throughput mode or a closed-loop AI-driven mode.

### CROSS REFERENCE TO RELATED APPLICATIONS

The present document is a Non-Provisional patent application that claims benefit to U.S. Provisional Patent Application No. 63/794,881 filed on Apr. 25, 2025, which is herein incorporated by reference in its entirety

### FIELD

The present disclosure generally relates to semiconductor fabrication technologies including spin-coating; and in particular to autonomous spin-coating via inventive artificial intelligence (AI) optimized thin film processes.

### BACKGROUND

Uniform, repeatable spin-coated films are a cornerstone of modern semiconductor manufacturing, whether the layer is a thin photoresist layer, a low-k spin-on dielectric, or a sol-gel oxide. However, initial recipe development and technology transfer still rely on empirical design-of-experiments campaigns that can consume multiple engineer-days for every new chemistry or thickness target.

It is with these observations in mind, among others, that various aspects of the present disclosure were conceived and developed.

### SUMMARY

Systems and methods for autonomous spin-coating for AI-optimized thin-film processes are disclosed. In some embodiments, a micro-laboratory platform integrates automated solution handling, spin coating, baking, robotic substrate transfer, and inline metrology under control of a centralized controller and communication platform. Measurement data generated during or after formation of a thin film can be used to evaluate one or more film properties relative to a predefined target, and an optimization routine can update a spin-coating recipe for one or more subsequent runs. In this manner, the disclosed system can iteratively refine thin-film process conditions with reduced manual intervention.

Systems and methods for an autonomous spin-coating micro-lab for AI-optimized thin-film processes are disclosed. In some embodiments, the disclosed system is a self-driving laboratory (SDL) platform for the autonomous synthesis and characterization of thin films on a variety of substrates. The platform can combine robotic substrate handling, programmable liquid dispensing onto a spin coater, controlled thermal annealing, and multi-modal characterization, including electrical, optical, and imaging measurements, into a single coordinated workflow. The platform can be operated by orchestration software built on open-source packages and can support both high-throughput experimentation across predetermined parameter sets and closed-loop, AI-driven optimization of process parameters.

In some embodiments, the platform comprises a central robotic manipulator that transports substrates between a series of fixed processing and characterization stations. Each station can be configured for a specific function and can be positioned within a working envelope of the robotic arm. The manipulator and stations can operate within a shared coordinate frame, thereby enabling deterministic and repeatable execution of multi-step experimental workflows on the same physical sample without manual intervention between steps. In some embodiments, the robotic manipulator can comprise a SCARA (Selective Compliance Articulated Robot Arm)-type robotic manipulator or another suitable robotic arm of comparable repeatability.

In some embodiments, the robotic manipulator is equipped with interchangeable end-effectors. For example, a precision gripper can be used for substrate handling and a liquid-dispensing end-effector such as a precision pipetting head can be used for programmable liquid dispensing. Because both end-effectors can be mounted on the same robotic arm and can operate within a shared coordinate frame, the platform can perform both substrate transport and liquid handling with a single mechanical system. This consolidation can reduce hardware footprint and avoid alignment and handoff complexity associated with separate transport and dispensing robots.

In some embodiments, liquid deposition and spin coating are performed at a single integrated station. A substrate can be placed on a spin coater chuck, and a pipetting end-effector can dispense programmed volumes of precursor or reagent solution directly onto the substrate while the substrate is held on the chuck. Because dispense location, dispense volume, dispense rate, and number of dispense events can all be software controlled, the system can support static and dynamic dispensing protocols and can be programmed to produce sequential or stratified depositions on the same substrate. Spin parameters, including spin speed, acceleration profile, and duration, can likewise be software controlled to enable reproducible film formation and systematic exploration of spin parameter space. Co-locating dispensing and spin coating in a single station can eliminate transfer of wet substrates between stages and minimize time between dispense and spin.

In some embodiments, after spin coating, the robotic manipulator transfers the substrate to an annealing station, where the deposited film is thermally processed under a controlled temperature profile. The annealing station can support programmable temperature setpoints, ramp rates, and dwell times. In some embodiments, the substrate is then transferred to a plurality of characterization stations, including a four-point probe station for electrical characterization, a UV-Vis station for optical characterization, and an imaging station for high-magnification visual characterization. The imaging station can provide visual information on film morphology, uniformity, defects such as cracks or pinholes, and macroscopic features that may correlate with electrical or optical performance. Together, the electrical, optical, and imaging measurements can provide a multi-modal description of each sample for human interpretation and for AI-driven optimization.

In some embodiments, the platform is operated under unified orchestration software that coordinates the robotic manipulator, end-effectors, and the processing and characterization stations, and provides an abstraction layer through which experimental campaigns are specified and executed. The platform may be operated in a high-throughput mode, in which the system autonomously executes a predetermined set of experimental parameters across a defined parameter space, or in a closed-loop AI-driven mode, in which an AI model determines parameters of each successive experiment based on results of preceding experiments. The orchestration software can pass measurements from the characterization stations to the model and can return the model’s recommended next experiment to the platform for execution.

In some embodiments, the framework is agnostic to the specific AI technique used and can accommodate Bayesian optimization, active learning, reinforcement learning, evolutionary strategies, or other optimization approaches without changes to the underlying hardware. The platform can be configured for processing a wide range of substrates, including glass, silicon, transparent conducting oxides, polymeric substrates, and metal foils, and can admit additional processing stations or characterization stations in other embodiments. In this manner, the disclosed platform can provide a compact, deterministic system architecture suitable for academic, institutional, or industrial environments in which thin-film synthesis and multi-modal characterization are performed end-to-end without operator intervention.

In one set of illustrative examples, the inventive concept can take the form of a system for autonomous processing of a thin film on a substrate. In some embodiments, the system comprises a robotic manipulator configured to operate within a working envelope encompassing a plurality of stations and to selectively operate with interchangeable end-effectors, the interchangeable end-effectors including a substrate-handling end-effector and a liquid-dispensing end-effector. The system can further comprise a dispensing and spin coating station configured to receive the substrate and to receive a coating solution dispensed onto the substrate while the substrate is supported on a spin coater chuck, a thermal processing station configured to thermally process the substrate after spin coating, one or more characterization stations configured to generate measurement data associated with the thin film, and a controller configured to coordinate operation of the robotic manipulator, the dispensing and spin coating station, the thermal processing station, and the one or more characterization stations, and to select parameters for a subsequent experiment based on the measurement data to move a film property toward a predefined target or process objective.

In some embodiments, the robotic manipulator and the plurality of stations operate within a shared coordinate frame such that the same physical substrate is transferred among the plurality of stations without manual intervention. In some embodiments, the substrate-handling end-effector comprises a gripper and the liquid-dispensing end-effector comprises a pipetting head. In some embodiments, the dispensing and spin coating station is configured such that dispense location, dispense volume, dispense rate, number of dispense events, spin speed, acceleration profile, and spin duration are software controlled. In some embodiments, the thermal processing station is configured to operate according to programmable temperature setpoints, ramp rates, and dwell times. In some embodiments, the one or more characterization stations comprise a four-point probe station, an optical characterization station, and an imaging station configured to generate electrical, optical, and image-based measurement data for the same physical substrate.

In another set of illustrative examples, the inventive concept can take the form of a method for autonomous processing of a thin film on a substrate. In some embodiments, the method comprises placing, by a robotic manipulator, the substrate at a dispensing and spin coating station; dispensing, by a liquid-dispensing end-effector of the robotic manipulator, a coating solution onto the substrate while the substrate is supported on a spin coater chuck; spin coating the substrate according to a spin-coating recipe; transferring, by the robotic manipulator, the substrate to a thermal processing station and thermally processing the substrate; transferring, by the robotic manipulator, the substrate to one or more characterization stations and generating measurement data associated with the thin film; evaluating the measurement data relative to a predefined target or process objective; and selecting parameters for a subsequent experiment based on the evaluating step.

In some embodiments, selecting parameters for the subsequent experiment comprises autonomously executing a predetermined set of experimental parameters across a defined parameter space in a high-throughput mode. In some embodiments, selecting parameters for the subsequent experiment comprises determining, with an optimization engine, parameters for a successive experiment based on results of one or more preceding experiments in a closed-loop mode. In some embodiments, the optimization engine is configured to implement one or more of Bayesian optimization, active learning, reinforcement learning, and evolutionary strategies. In some embodiments, the method is performed on a wide range of substrates and may further include electrical characterization, optical characterization, imaging-based characterization, or combinations thereof.

The foregoing examples broadly outline various aspects, features, and technical advantages of examples according to the disclosure in order that the detailed description that follows may be better understood. It is further appreciated that the above operations described in the context of the illustrative example method, device, and computer-readable medium are not required and that one or more operations may be excluded and/or other additional operations discussed herein may be included. Additional features and advantages will be described hereinafter. The conception and specific examples illustrated and described herein may be readily utilized as a basis for modifying or designing other structures for carrying out the same purposes of the present disclosure. Such equivalent constructions do not depart from the spirit and scope of the appended claims.

### BRIEF DESCRIPTION OF THE DRAWINGS

FIG. 1 is a schematic block diagram of an example autonomous spin-coating system for AI-optimized thin-film processes, in accordance with aspects of the present disclosure.

FIG. 2 is a flowchart of an example method for autonomous optimization of a spin-coating process for forming a thin film on a substrate, in accordance with aspects of the present disclosure.

FIG. 3 is a schematic diagram of an example autonomous thin-film processing platform including a robotic manipulator, a dispensing and spin coating station, an annealing station, and a plurality of characterization stations, in accordance with aspects of the present disclosure.

FIG. 4 is a schematic diagram of an example robotic manipulator and interchangeable end-effector arrangement for substrate handling and programmable liquid dispensing, in accordance with aspects of the present disclosure.

FIG. 5 is a schematic diagram of an example orchestration and control framework for operating the autonomous thin-film processing platform in a high-throughput mode and a closed-loop AI-driven mode, in accordance with aspects of the present disclosure.

FIG. 6 is a flowchart of an example autonomous thin-film processing and characterization workflow including deposition, thermal processing, characterization, and iterative recipe refinement, in accordance with aspects of the present disclosure.

FIG. 7A is a perspective view of an example prototype implementation of an autonomous thin-film processing platform including a SCARA robotic manipulator, liquid-handling components, processing stations, and characterization stations, in accordance with aspects of the present disclosure.

FIG. 7B is another perspective view of the example prototype implementation of FIG. 7A, in accordance with aspects of the present disclosure.

Corresponding reference characters indicate corresponding elements among the view of the drawings. The headings used in the figures do not limit the scope of the claims.

### DETAILED DESCRIPTION

Various examples of systems and methods for autonomous thin-film processing are disclosed. In some embodiments, the disclosed technology includes a self-driving laboratory platform configured to autonomously synthesize, process, and characterize thin films on a variety of substrates. The platform can integrate robotic substrate handling, programmable liquid dispensing, spin coating, thermal processing, and one or more characterization operations into a coordinated workflow that reduces manual intervention and improves repeatability.

In some examples, the inventive concept includes a system comprising a self-driving laboratory configured for autonomous optimization of spin-coating conditions. The system can include and can integrate automated solution handling, a vacuum spin coater, a programmable hotplate, and a robotic gripper to autonomously perform spin coating and baking. A camera and a low-cost inline LED (light-emitting diode) reflectometer can capture real-time data on film uniformity and thickness. The system can include various semiconductor fabrication subsystems. All subsystems can communicate through a centralized communication platform (e.g., software BUS). The centralized communication platform can include orchestration software that uses Bayesian optimization to iteratively refine spin-coating recipes to achieve predefined targets. Thin-film processes can be validated with the system using surrogate polymers on glass substrates, followed by demonstrations with commercial photoresists. The system can include mechanical designs, control software, detailed analytical scripts, and comprehensive documentation. In general, the system can be configured for AI-enabled process development and self-driving laboratory functions.

The system can include various design and modeling implementations via mechanical fixtures via computer-rendered images and fabricating mounts via 3D (three-dimensional) printing or CNC (Computer Numeric Control). The system can include wired and programmed microcontrollers (Arduino/ESP32 or Raspberry Pi) to drive LEDs, spectrometers, cameras, motors, and safety interlocks for the micro-lab and thin-film processes. On the software side, the system can include Python routines for thin-film reflectometry fitting, OpenCV-based vision analytics, and Bayesian-optimization workflows. The system can produce or is otherwise configured for spin-coating and soft-bake protocols.

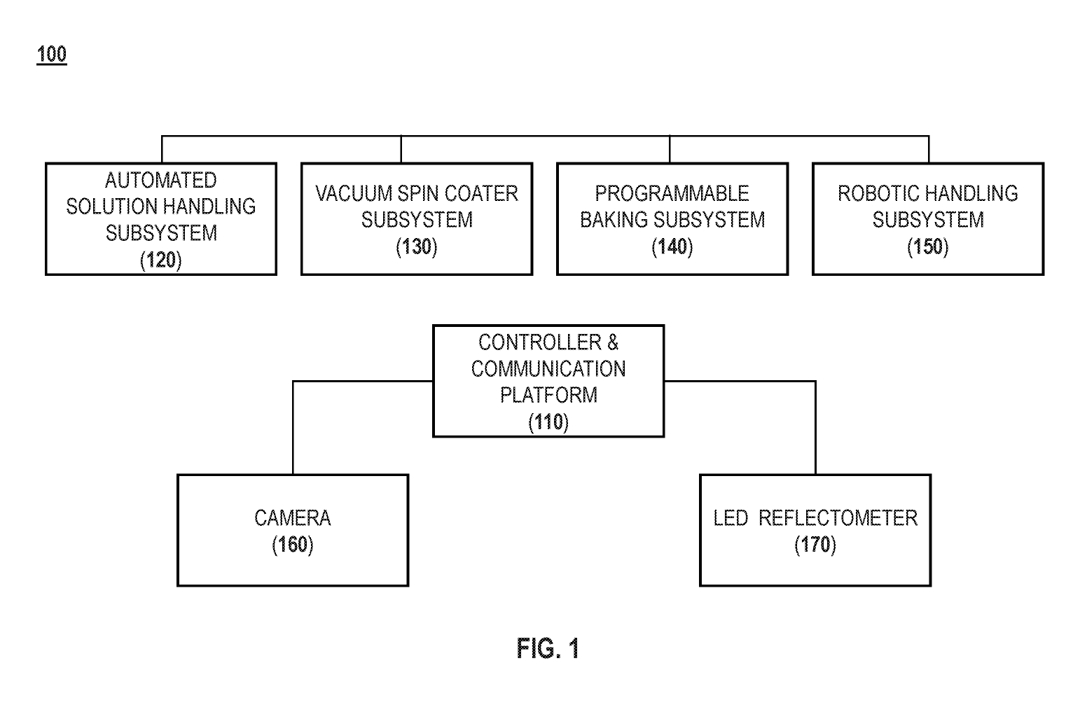

Referring to FIG. 1, an example autonomous spin-coating system 100 is shown. In some embodiments, the system 100 includes a controller and communication platform 110, an automated solution handling subsystem 120, a vacuum spin coater subsystem 130, a programmable baking subsystem 140, a robotic handling subsystem 150, a camera 160, and a reflectometer 170.

The controller and communication platform 110 can be configured to communicate with and coordinate operation of the various subsystems of the system 100. In some embodiments, the controller and communication platform 110 includes one or more processors, memory, communication interfaces, and orchestration software configured to schedule, initiate, monitor, and modify execution of spin-coating runs. The controller and communication platform 110 can further be configured to receive sensor data, evaluate one or more film properties relative to a predefined target, and update one or more process parameters for a subsequent run.

The automated solution handling subsystem 120 can be configured to store, select, meter, and dispense one or more coating solutions onto a substrate. In some embodiments, the automated solution handling subsystem 120 includes one or more pumps, dispensers, reservoirs, valves, or related fluid-handling components configured to deliver a controlled amount of coating solution to the substrate. The automated solution handling subsystem 120 can operate according to commands received from the controller and communication platform 110.

The vacuum spin coater subsystem 130 can be configured to receive the substrate and rotate the substrate according to a spin-coating recipe to form a thin film from the coating solution. In some embodiments, the spin-coating recipe can include one or more parameters such as spin speed, spin duration, acceleration, dispense timing, or dispense volume. The vacuum spin coater subsystem 130 can include a vacuum chuck or other holding structure configured to secure the substrate during rotation.

The programmable baking subsystem 140 can be configured to bake the substrate after spin coating. In some embodiments, the programmable baking subsystem 140 includes a hotplate configured to operate at one or more selected temperatures for one or more selected durations. The programmable baking subsystem 140 can be used, for example, to perform a soft-bake or other post-coating thermal treatment.

The robotic handling subsystem 150 can be configured to autonomously transfer the substrate among the automated solution handling subsystem 120, the vacuum spin coater subsystem 130, and the programmable baking subsystem 140. In some embodiments, the robotic handling subsystem 150 includes a robotic gripper, arm, end effector, linear stage, or other automated transfer mechanism. The robotic handling subsystem 150 can thereby reduce or eliminate manual movement of substrates between process stations.

The camera 160 can be configured to generate image data associated with the coated substrate or the thin film formed thereon. In some embodiments, the image data can be processed to determine one or more film characteristics, such as film uniformity, visible defects, coverage, streaking, pooling, or other visually detectable attributes.

The reflectometer 170 can be configured to generate optical measurement data associated with the thin film. In some embodiments, the reflectometer 170 is an inline LED reflectometer configured to determine or estimate film thickness based on reflected light. The reflectometer 170 can provide thickness-related measurement data to the controller and communication platform 110 for evaluation and use in recipe refinement.

In some embodiments, the controller and communication platform 110 can receive measurement data from the camera 160 and the reflectometer 170, determine one or more film properties based on the measurement data, compare the one or more film properties to a predefined target, and update one or more parameters of the spin-coating recipe for a subsequent run. In this manner, the system 100 can operate as an autonomous or semi-autonomous micro-laboratory for iterative optimization of thin-film formation processes.

Although FIG. 1 illustrates a particular arrangement of components, it should be understood that the arrangement is provided by way of example only. In other embodiments, components may be added, removed, combined, distributed, or arranged differently. For example, one or more sensing devices, thermal processing devices, substrate transfer devices, or control devices may be incorporated without departing from the scope of the present disclosure.

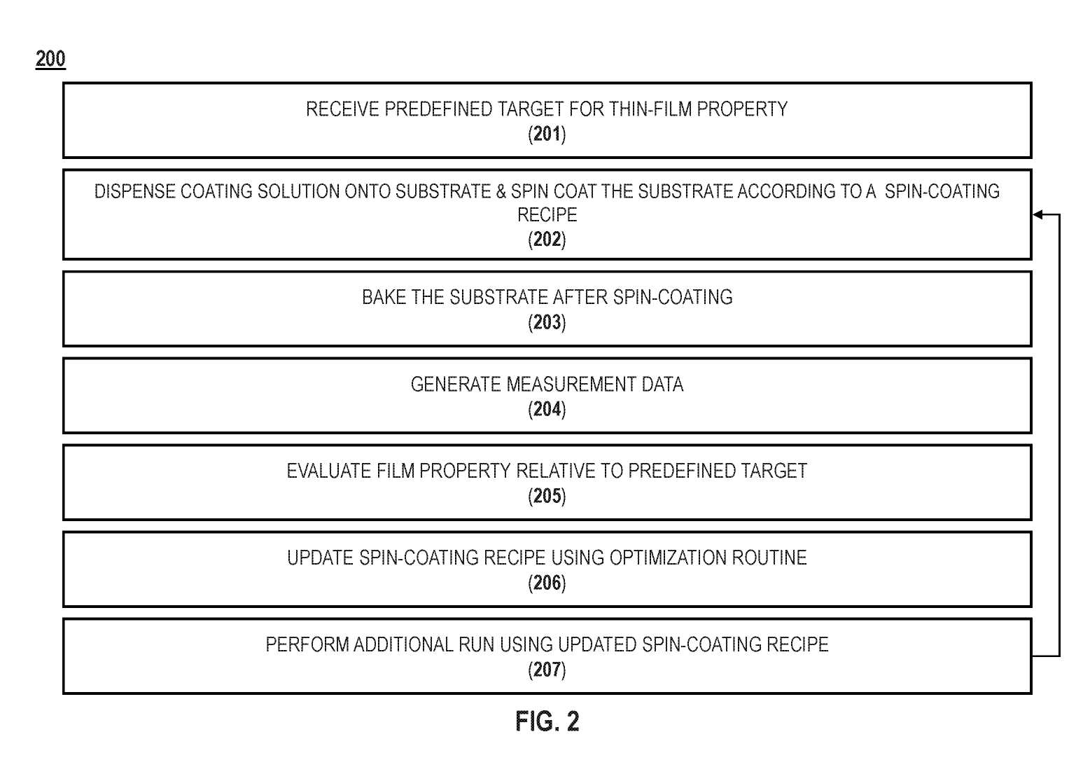

Referring to FIG. 2, an example method 200 for autonomous optimization of a spin-coating process is shown. At operation 201, a predefined target for a thin-film property is received. In some embodiments, the predefined target can include a target thickness, a target uniformity, a target defect level, or another target film characteristic.

At operation 202, a coating solution is dispensed onto a substrate and the substrate is spin coated according to a spin-coating recipe. In some embodiments, the spin-coating recipe includes one or more process parameters such as dispense volume, dispense timing, spin speed, spin duration, acceleration, or other variables used to influence formation of the thin film.

At operation 203, the substrate is baked after spin coating. In some embodiments, baking can include heating the substrate at a selected temperature for a selected duration to remove solvent, stabilize the thin film, or otherwise condition the deposited material.

At operation 204, measurement data is generated. In some embodiments, the measurement data can include image data, reflectometry data, thickness data, uniformity data, defect data, or combinations thereof. The measurement data can be generated using one or more metrology devices, such as the camera 160 and the reflectometer 170 of FIG. 1.

At operation 205, a film property is evaluated relative to the predefined target. In some embodiments, this evaluation can include determining a difference between a measured film thickness and a target thickness, determining a uniformity metric, determining whether a defect threshold has been satisfied, or computing another quality metric associated with the thin film.

At operation 206, the spin-coating recipe is updated using an optimization routine. In some embodiments, the optimization routine can include a Bayesian optimization routine or another iterative optimization technique configured to modify one or more process parameters based on prior run results. The updated recipe can be selected to move one or more measured film properties toward the predefined target.

At operation 207, an additional run is performed using the updated spin-coating recipe. In some embodiments, operations 202-207 can be repeated until the predefined target is satisfied, a termination criterion is reached, or a selected number of runs has been completed.

The operations of FIG. 2 are illustrated in one example order for purposes of explanation. It should be understood that, in other embodiments, one or more operations may be omitted, repeated, combined, reordered, or supplemented with additional operations. For example, one or more calibration operations, substrate inspection operations, error-handling operations, or data logging operations may be performed without departing from the scope of the present disclosure.

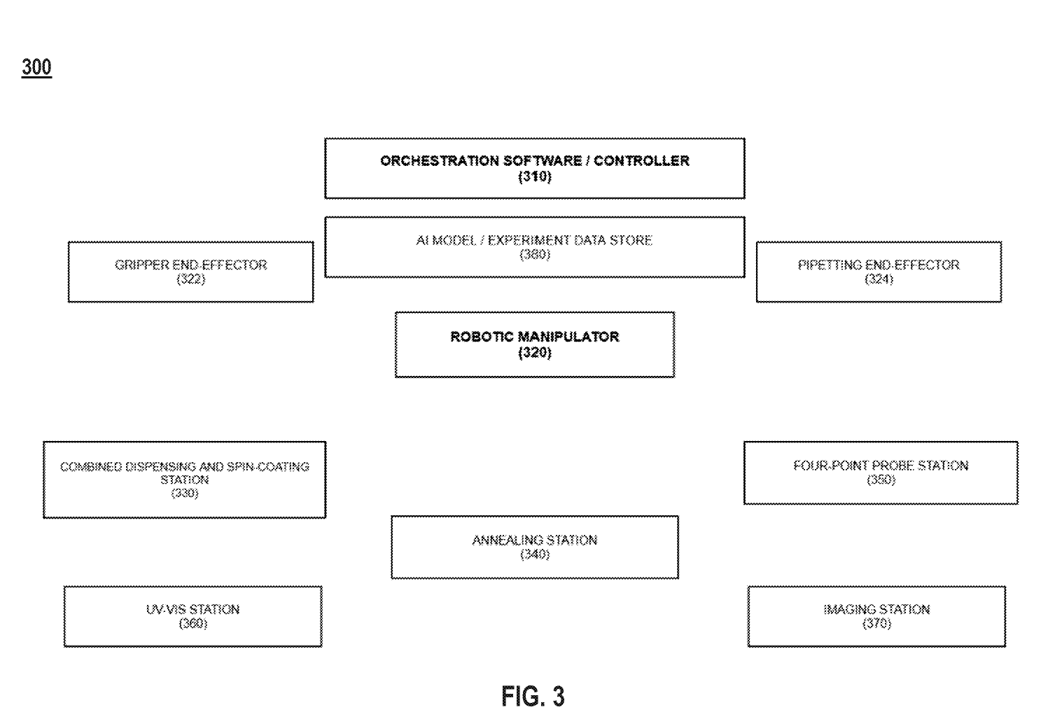

Referring to FIG. 3, an example autonomous thin-film processing platform 300 is shown. In some embodiments, the platform 300 includes a robotic manipulator 310, a dispensing and spin coating station 320, an annealing station 330, a four-point probe station 340, an optical characterization station 350, such as a UV-Vis characterization station, an imaging station 360, and a controller and orchestration platform 370.

In some embodiments, the robotic manipulator 310 serves as a central transport element of the platform 300 and moves a substrate among fixed processing and characterization stations in a deterministic sequence. The robotic manipulator 310 and the stations of the platform 300 can operate within a shared coordinate frame, thereby enabling repeatable execution of multi-step workflows on the same physical sample. In some embodiments, the robotic manipulator 310 may comprise a SCARA-type robotic arm. In other embodiments, the robotic manipulator 310 may comprise another articulated, Cartesian, or collaborative robotic arm having sufficient positional repeatability for substrate transport and related operations.

The dispensing and spin coating station 320 can be configured to receive a substrate, dispense one or more precursor or coating solutions onto the substrate, and spin coat the substrate to form a thin film. In some embodiments, liquid deposition and spin coating are co-located at the dispensing and spin coating station 320, such that the coating solution is dispensed directly onto the substrate while the substrate is held on a spin coater chuck. This arrangement can reduce or eliminate transfer of a wet substrate between deposition and spin operations and can reduce the time between dispense and spin.

The annealing station 330 can be configured to thermally process the substrate after spin coating. In some embodiments, the annealing station 330 supports programmable temperature setpoints, ramp rates, and dwell times for thermal treatment of the deposited film. The annealing operation can, for example, facilitate solvent removal, densification, phase development, curing, or chemical conversion of the deposited material.

The four-point probe station 340 can be configured to measure one or more electrical properties of the deposited film, such as sheet resistance. In some embodiments, probe engagement, contact verification, and electrical measurement can be performed automatically. The optical characterization station 350 can be configured to measure optical properties of the film, such as absorbance and transmittance. In some embodiments, the optical characterization station 350 can comprise a UV-Vis characterization station. The imaging station 360 can be configured to capture high-magnification images of the deposited film to assess film morphology, uniformity, coverage, or defects including cracks and pinholes. In some embodiments, the four-point probe station 340, optical characterization station 350, and imaging station 360 together provide a multi-modal characterization set for the same physical sample.

The controller and orchestration platform 370 can be configured to coordinate operation of the robotic manipulator 310, the dispensing and spin coating station 320, the annealing station 330, and the characterization stations 340, 350, and 360. In some embodiments, the controller and orchestration platform 370 can receive measurement data from one or more of the stations, evaluate one or more film properties relative to a predefined target, and generate updated process instructions for a subsequent run. Although FIG. 3 illustrates a particular arrangement of stations, it should be understood that additional stations may be added, stations may be removed, and the relative positions of the stations may vary in other embodiments.

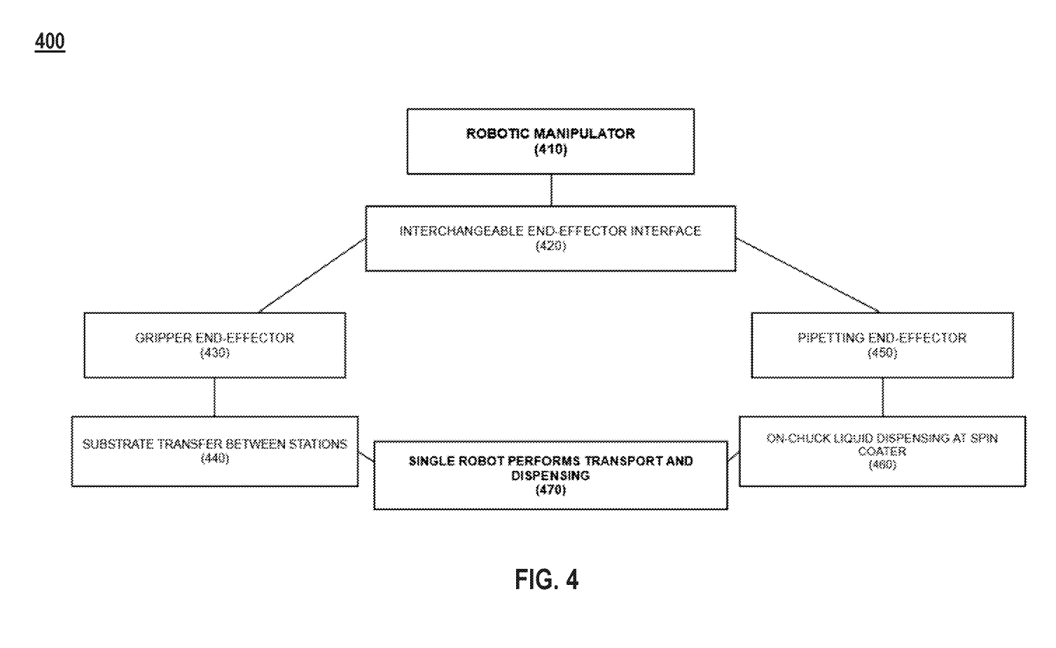

Referring to FIG. 4, an example robotic manipulator and interchangeable end-effector arrangement 400 is shown. In some embodiments, the arrangement 400 includes a robotic manipulator 410, a first end-effector 420, and a second end-effector 430. In some embodiments, the first end-effector 420 comprises a precision gripper configured for substrate handling, and the second end-effector 430 comprises a liquid-dispensing end-effector, such as a pipetting head, configured for programmable liquid dispensing.

In some embodiments, the robotic manipulator 410 is configured to operate with interchangeable end-effectors within a shared coordinate frame, such that the same robotic system can perform both substrate transport and liquid handling operations. For example, the robotic manipulator 410 can use the first end-effector 420 to place a substrate at a spin coater chuck or another station, and can use the second end-effector 430 to dispense a programmed amount of precursor or reagent solution onto the substrate. In this manner, a single robotic platform can provide both handling and dispensing functionality, which can reduce hardware footprint and reduce alignment complexity otherwise associated with separate robots.

In some embodiments, the liquid-dispensing end-effector of the second end-effector 430 can include a programmable precision pipetting system, such as a Hamilton pipetting system. However, the present disclosure is not limited to a particular pipetting subsystem, and other programmable liquid handling devices may be used.

In some embodiments, the robotic manipulator 410 can transfer substrates among a deposition station, a thermal processing station, and one or more characterization stations with sufficient positional repeatability that the same physical sample is processed and measured in a deterministic sequence. The shared coordinate frame and interchangeable end-effector arrangement shown in FIG. 4 can thereby support autonomous execution of multi-step thin-film synthesis and characterization workflows.

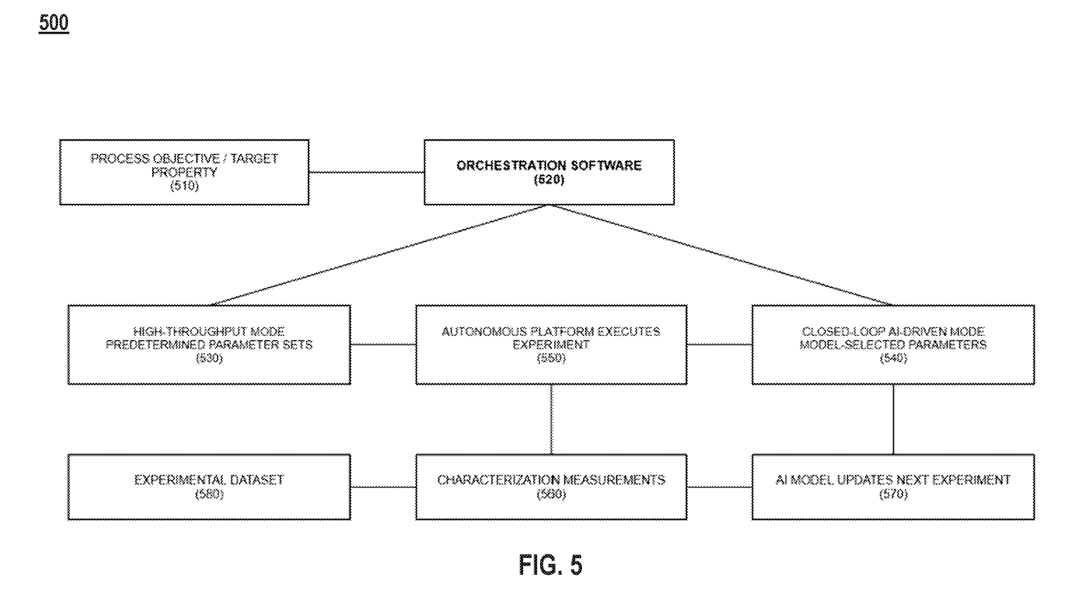

Referring to FIG. 5, an example orchestration and control framework 500 is shown. In some embodiments, the framework 500 includes an orchestration software layer 510, a processing and characterization platform 520, a data aggregation and analysis layer 530, and an optimization engine 540. In some embodiments, the orchestration software layer 510 coordinates operation of the robotic manipulator, end-effectors, and station-level subsystems, and serves as an abstraction layer through which experimental campaigns are specified and executed.

In some embodiments, the framework 500 can operate in a high-throughput mode. In the high-throughput mode, the orchestration software layer 510 causes the platform 520 to autonomously execute a predetermined set of experimental parameters across a defined parameter space, thereby generating a corresponding dataset without operator intervention. This mode can be useful for parameter sweeps, design-of-experiments campaigns, and generation of training data for subsequent model-based optimization.

In some embodiments, the framework 500 can also operate in a closed-loop AI-driven mode. In the closed-loop AI-driven mode, the optimization engine 540 receives measurement data from the data aggregation and analysis layer 530 and determines parameters for a subsequent experiment based on results of one or more preceding experiments. The orchestration software layer 510 can then cause the platform 520 to execute the next experiment according to the updated parameters. In some embodiments, the optimization engine 540 can optimize a defined process objective, such as thickness accuracy, film uniformity, sheet resistance, transmittance, or another performance metric associated with the thin film.

In some embodiments, the optimization engine 540 may implement one or more AI or machine-learning techniques, including Bayesian optimization, active learning, reinforcement learning, or evolutionary strategies. In some embodiments, the framework 500 is agnostic to the specific optimization technique used, such that different techniques may be employed without changing the underlying hardware architecture of the platform.

Although FIG. 5 illustrates a particular orchestration and control framework, it should be understood that data collection, analysis, optimization, and execution functions may be combined, distributed, reordered, or supplemented with additional modules in other embodiments. For example, data logging, quality-control screening, calibration, model confidence assessment, and exception handling modules may be incorporated without departing from the scope of the present disclosure.

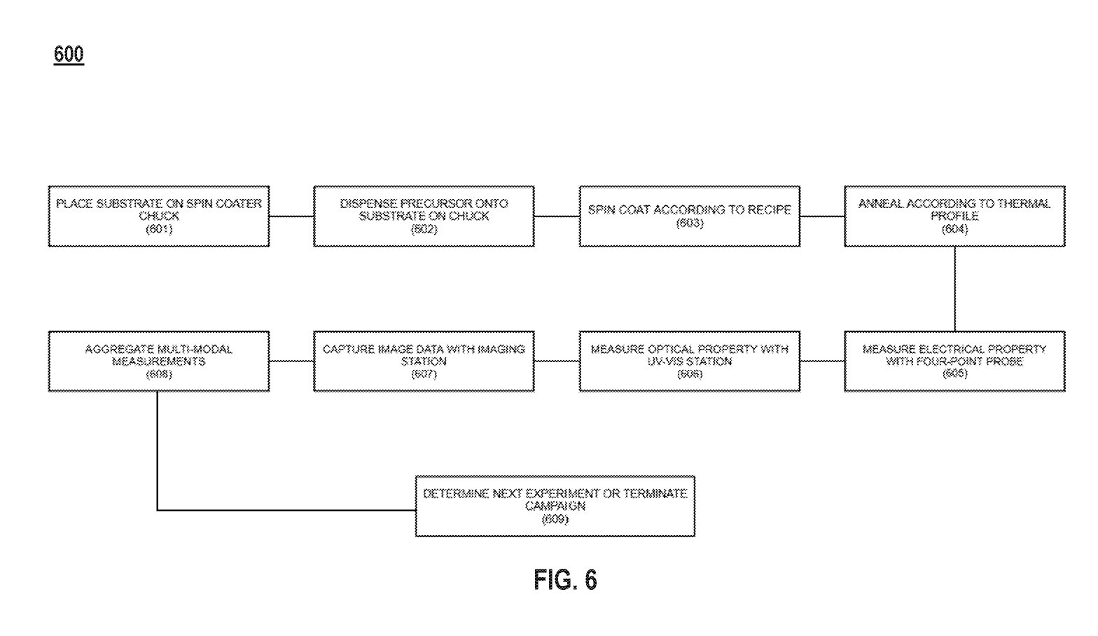

Referring to FIG. 6, an example autonomous thin-film processing and characterization workflow 600 is shown. In some embodiments, the workflow 600 begins by receiving a substrate and placing the substrate at a dispensing and spin coating station. A robotic manipulator can position the substrate on a spin coater chuck or other support structure for subsequent coating operations.

The workflow 600 can further include dispensing one or more coating solutions onto the substrate while the substrate is held at the spin coating station. In some embodiments, the location of dispense, dispense volume, dispense rate, and number of dispense events are software controlled. The workflow 600 can then include spin coating the substrate according to one or more spin parameters, such as spin speed, acceleration profile, and duration, to spread the deposited liquid into a thin film. In some embodiments, the workflow 600 supports both static and dynamic dispensing protocols, as well as sequential or stratified deposition protocols on the same substrate.

After spin coating, the workflow 600 can include transferring the substrate to an annealing station and thermally processing the deposited film under a controlled temperature profile. In some embodiments, the thermal treatment can include one or more programmable temperature setpoints, ramp rates, and dwell times.

The workflow 600 can further include transferring the substrate to one or more characterization stations. In some embodiments, characterization can include four-point probe measurement of an electrical property such as sheet resistance, UV-Vis measurement of one or more optical properties such as absorbance or transmittance, and imaging-based evaluation of morphology, uniformity, or defects. In some embodiments, measurement data from the characterization operations can be aggregated to provide a multi-modal description of the deposited film.

In some embodiments, the workflow 600 can further include evaluating one or more measured film properties relative to a predefined target or process objective, and updating one or more process parameters for a subsequent run based on the evaluation. In some embodiments, the subsequent run can be selected according to a predetermined campaign in a high-throughput mode. In other embodiments, the subsequent run can be selected by an AI-driven optimization routine in a closed-loop mode. The workflow 600 can be repeated until a termination criterion is reached, such as attainment of a target film property, completion of a predetermined number of runs, or satisfaction of a quality threshold.

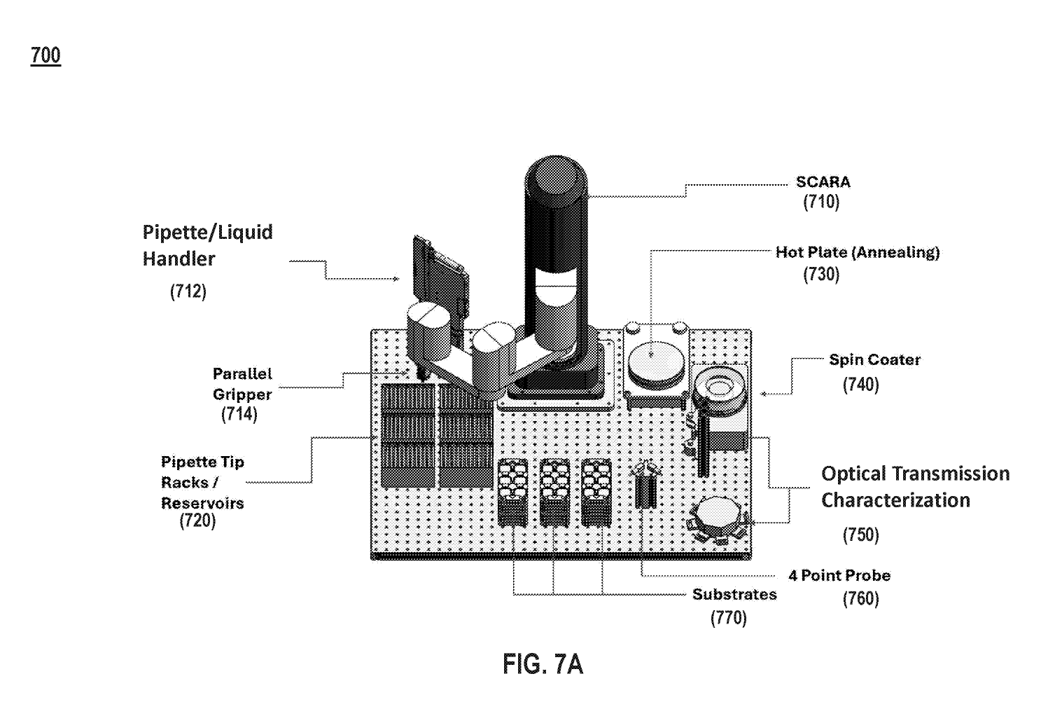

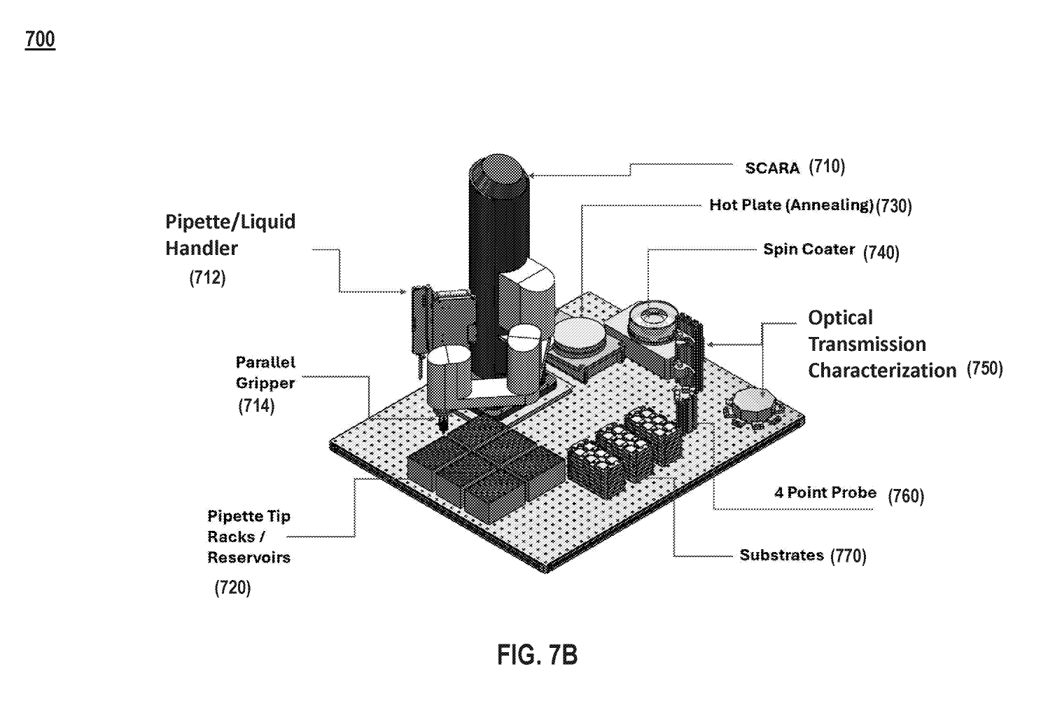

Referring to FIGS. 7A and 7B, example perspective views of a prototype implementation 700 of an autonomous thin-film processing platform are shown. In some embodiments, the prototype implementation 700 includes a SCARA robotic manipulator 710, a liquid-dispensing end-effector 712, shown as a pipetter or liquid handler, a parallel gripper 714, pipette tip racks and/or reservoirs 720, a hot plate or annealing station 730, a spin coater 740, an optical transmission characterization station 750, which can provide one example of an optical characterization station, a four-point probe station 760, and one or more substrates 770.

In some embodiments, the SCARA robotic manipulator 710 provides a central transport and actuation element for the platform 700. The manipulator 710 can operate with different end-effectors, including the liquid-dispensing end-effector 712 for programmable liquid dispensing and the parallel gripper 714 for substrate handling and transfer.

In some embodiments, the pipette tip racks and/or reservoirs 720 store pipette tips, precursor solutions, reagents, or other liquids used during thin-film processing. The liquid-dispensing end-effector 712 can draw liquid from the pipette tip racks and/or reservoirs 720 and dispense the liquid onto a substrate positioned at the spin coater 740.

After coating, the substrate can be transferred to the hot plate or annealing station 730 for thermal processing. In some embodiments, the hot plate or annealing station 730 is configured to apply a selected temperature profile to the substrate to facilitate solvent removal, curing, densification, phase development, or chemical conversion of the deposited material.

In some embodiments, the coated substrate can be characterized at the optical transmission characterization station 750 and the four-point probe station 760. The optical transmission characterization station 750 can be configured to measure one or more optical properties of the deposited film, such as transmittance or absorbance, and the four-point probe station 760 can be configured to measure one or more electrical properties of the film, such as sheet resistance. The substrates 770 can be held in one or more substrate carriers or stacks prior to and/or after processing.

FIGS. 7A and 7B illustrate one example physical layout of the prototype implementation 700. The illustrated arrangement is provided by way of example only, and the relative positions, number, and type of stations and components may vary in other embodiments. For example, additional characterization stations, additional processing stations, or different robotic architectures may be used without departing from the scope of the present disclosure.

It should be understood from the foregoing that, while particular embodiments have been illustrated and described, various modifications can be made thereto without departing from the spirit and scope of the invention as will be apparent to those skilled in the art. Such changes and modifications are within the scope and teachings of this invention as defined in the claims appended hereto.

What is claimed is:

1. A system for autonomous spin-coating of a thin film on a substrate, the system comprising:
a solution handling subsystem configured to dispense a coating solution onto the substrate;
a spin-coating subsystem comprising a vacuum spin coater configured to rotate the substrate according to a spin-coating recipe;
a baking subsystem comprising a programmable hotplate configured to bake the substrate after spin coating;
a robotic handling subsystem comprising a robotic gripper configured to transfer the substrate among the solution handling subsystem, the spin-coating subsystem, and the baking subsystem;
one or more metrology subsystems configured to generate measurement data associated with at least one property of the thin film; and
a controller in communication with the solution handling subsystem, the spin-coating subsystem, the baking subsystem, the robotic handling subsystem, and the one or more metrology subsystems, the controller being configured to autonomously execute a plurality of spin-coating runs, evaluate the measurement data from the plurality of spin-coating runs, and update the spin-coating recipe to move a film property toward a predefined target.

2. The system of claim 1, wherein the one or more metrology subsystems comprise a camera and an inline reflectometer configured to generate the measurement data indicative of film uniformity and film thickness.

3. The system of claim 1, wherein the controller comprises a centralized communication platform and orchestration software configured to coordinate operation of a plurality of semiconductor fabrication subsystems and to iteratively refine the spin-coating recipe using an optimization routine based on the measurement data.

4. The system of claim 1, wherein the spin-coating recipe comprises one or more of a dispense volume, a dispense rate, a dispense location, a spin speed, a spin duration, a spin acceleration, a bake temperature, and a bake duration.

5. The system of claim 1, wherein the controller is configured to determine a thickness value of the thin film based on reflectometry data generated by the inline reflectometer.

6. The system of claim 1, wherein the controller is configured to determine a film uniformity metric based on image data generated by the camera.

7. The system of claim 1, wherein the controller is configured to generate a quality score for each spin-coating run based on a difference between a measured film property and the predefined target.

8. The system of claim 1, wherein the controller is configured to select a subsequent spin-coating recipe based on measurement data from prior spin-coating runs.

9. The system of claim 1, wherein the optimization routine comprises a Bayesian optimization routine configured to iteratively refine the spin-coating recipe.

10. The system of claim 1, wherein the robotic handling subsystem is configured to autonomously transfer the substrate from the spin-coating subsystem to the baking subsystem after completion of a spin-coating operation.

11. A method for autonomous optimization of a spin-coating process for forming a thin film on a substrate, the method comprising:
dispensing a coating solution onto the substrate;
spin coating the substrate according to a spin-coating recipe;
baking the substrate after spin coating;
generating measurement data associated with at least one property of the thin film;
evaluating the measurement data relative to a predefined target for the thin film;
updating the spin-coating recipe based on the evaluating; and
performing an additional spin-coating run using the updated spin-coating recipe.

12. The method of claim 11, wherein generating the measurement data comprises capturing image data of the thin film with a camera.

13. The method of claim 11, wherein generating the measurement data comprises obtaining reflectometry data from an inline reflectometer and determining a thickness of the thin film based on the reflectometry data.

14. The method of claim 11, wherein evaluating the measurement data comprises determining a film uniformity metric for the thin film.

15. The method of claim 11, wherein updating the spin-coating recipe comprises modifying one or more of a dispense volume, a dispense rate, a spin speed, a spin duration, a spin acceleration, a bake temperature, and a bake duration.

16. The method of claim 11, wherein updating the spin-coating recipe comprises applying a Bayesian optimization routine to measurement data from a plurality of prior spin-coating runs.

17. The method of claim 11, further comprising autonomously transferring the substrate with a robotic gripper between a solution handling station, a spin-coating station, and a baking station.

18. The method of claim 11, wherein the predefined target comprises a target film thickness.

19. The method of claim 11, wherein the predefined target comprises a target film uniformity.

20. The method of claim 11, further comprising repeating the dispensing, spin coating, baking, generating, evaluating, and updating until the at least one property of the thin film satisfies the predefined target.
